(19) United States
(12) Patent Application Publication
(10) Pub. No.: US 2021/0398786 A1
(43) Pub. Date: Dec. 23, 2021

(54) PLASMA PROCESSING APPARATUS

(71) Applicant: TOKYO ELECTRON LIMITED, Tokyo (JP)

(72) Inventors: Taro IKEDA, Nirasaki City, Yamanashi (JP); Toshifumi KITAHARA, Tokyo (JP)

(21) Appl. No.: 17/297,190

(22) PCT Filed: Nov. 26, 2019
(86) PCT No.: PCT/JP2019/046208

§ 371 Date: May 26, 2021

(30) Foreign Application Priority Data
Dec. 6, 2018 (JP) 2018-229221

(51) Int. Cl. H01J 37/32

(52) U.S. Cl. CPC H01J 37/32935; H01J 2237/3321; H01J 37/32449; H01J 37/32577

(57) ABSTRACT

Improvement of plasma heat dissipation has been required with respect to a plasma processing apparatus. The plasma processing apparatus includes a dielectric, a conductive film, a heat radiation film, and an electrode. The dielectric has one surface which faces a space for plasma generation. The conductive film is installed on the other surface of the dielectric. The heat radiation film is installed on the conductive film, and has a higher emissivity than the conductive film. The electrode is electrically connected to the conductive film so as to apply electric power for plasma generation.

### TECHNICAL FIELD

An exemplary embodiment of the present disclosure relates to a plasma processing apparatus.

### BACKGROUND

In manufacturing certain electronic devices, a plasma processing apparatus is used. One of the plasma processing apparatus may be a capacitively-coupled plasma processing apparatus. The capacitively-coupled plasma processing apparatus may use radio-frequency waves having a frequency in the very-high-frequency (VHF) band for plasma generation is attracting attention. The VHF band is a frequency band in the range of about 30 MHz to 300 MHz. Since the plasma processing apparatus generates heat, various heat dissipation structures are considered. Patent Document 1 discloses a shower head including a heat transfer member, and Patent Document 2 discloses a metal-bonded body in which a ceramic plate is attached to a metal support using an acrylic bonding sheet.

### PRIOR ART DOCUMENTS

### Patent Documents

Patent Document 1: Japanese laid-open publication No. 2009-10101
Patent Document 2: Japanese laid-open publication No. 2015-134714

Improvement of plasma heat dissipation has been required with respect to a plasma processing apparatus.

### SUMMARY

In an exemplary embodiment, a plasma processing apparatus is provided. The plasma processing apparatus includes a dielectric, a conductive film, a heat radiation film, and an electrode. The dielectric has one surface which faces a space for plasma generation. The conductive film is installed on the other surface of the dielectric. The heat radiation film is installed on the conductive film, and has a higher emissivity than the conductive film. The electrode is electrically connected to the conductive film so as to apply electric power for plasma generation.

With a plasma processing apparatus according to an exemplary embodiment, it is possible to improve plasma heat dissipation.

### BRIEF DESCRIPTION OF DRAWINGS

FIG. 1 is a view illustrating a main structure of a plasma processing apparatus according to an exemplary embodiment.

FIG. 2 is a view illustrating a certain structure of the structure illustrated in FIG. 1.

FIG. 3 is a perspective view illustrating a structure of a laminated film according to an exemplary embodiment.

FIG. 4 is a view schematically illustrating a plasma processing apparatus according to an exemplary embodiment.

### DETAILED DESCRIPTION

Embodiments Hereinafter, various exemplary embodiments will be described.

In an exemplary embodiment, a plasma processing apparatus is provided. The plasma processing apparatus includes a dielectric, a conductive film, a heat radiation film, and an electrode. The dielectric has one surface which faces a space for plasma generation. The conductive film is installed on the other surface of the dielectric. The heat radiation film is installed on the conductive film, and has a higher emissivity than the conductive film. The electrode is electrically connected to the conductive film so as to apply electric power for plasma generation.

When power for plasma generation is applied to the electrode, plasma is generated and the temperature of the dielectric facing the plasma rises. A conductive film is provided on the other surface of the dielectric. Since the conductive film is electrically connected to the electrode, the conductive film itself also functions as an electrode. As the temperature of the dielectric rises, the temperature of the conductive film also rises. A heat radiation film is provided on the conductive film. The higher the emissivity, the more efficiently heat can be radiated. Thus, it is possible to apply more power, and the allowable upper limit of power for plasma generation becomes higher. In other words, when the power supplied for plasma generation is the same, it is possible to lower the temperature of the dielectric.

In a plasma processing apparatus of an exemplary embodiment, a conductive electromagnetic shielding material is preferably provided between the conductive film and the electrode. When radio-frequency power such as VHF is used, radio-frequency electromagnetic waves may flow into a gas supply path through the gap between the conductive film and the electrode. Such electromagnetic waves apply energy to the gas, which may cause unintended electrical discharge or the like. Since the conductive electromagnetic shielding material is capable of filling the gap between the conductive film and the electrode, it is possible to suppress unintended electrical discharge.

In the plasma processing apparatus of an exemplary embodiment, an annular sealing material is provided between the dielectric and the electrode. Since it is possible to form a space inside the annular sealing material, it is possible to diffuse the gas supplied in this space in the radial direction and prevent the gas from leaking to the outside of the sealing material. This makes it possible to prevent the leaking gas from receiving radio-frequency power such as VHF and generating electrical discharge.

In the plasma processing apparatus of an exemplary embodiment, the thermal conductivity of the sealing material is 0.4 (W/mK) or more. When the thermal conductivity of the sealing material is high, the heat dissipation characteristic of the dielectric is improved, and thus it is possible to lower the temperature of the dielectric.

Hereinafter, various exemplary embodiments will be described in detail with reference to the drawings. In each of the drawings, the same or corresponding parts will be denoted by the same reference numerals, and a redundant description thereof will be omitted.

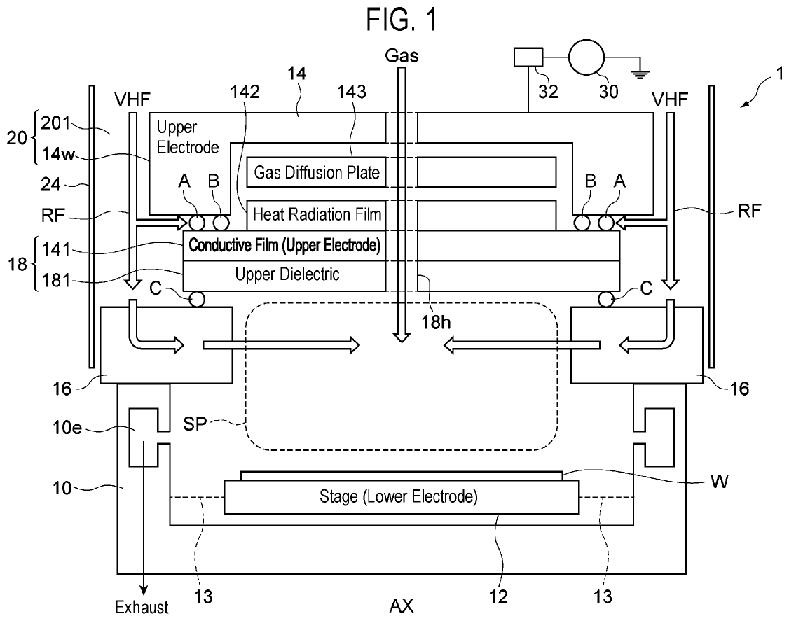

FIG. 1 is a view illustrating a main structure of a plasma processing apparatus according to an exemplary embodiment. The plasma processing apparatus 1 illustrated in FIG. 1 includes a processing container 10, a stage 12, an upper electrode 14, a shower plate 18 including a conductive film 141 (an upper electrode), an introduction part 16, a heat radiation film 142, and a gas diffusion plate 143. The shower plate 18 includes an upper dielectric 181 as the main body.

The upper dielectric 181 has one surface (a bottom surface) facing a space for plasma generation. The conductive film 141 is provided on the other surface (an upper surface) of the upper dielectric 181. The heat radiation film 142 is provided on the conductive film 141, and has a higher emissivity than the conductive film 141. The upper electrode 14 is electrically connected to the conductive film 141 via a conductive electromagnetic shielding material A provided on the bottom surface of the peripheral portion thereof. The upper electrode 14 is provided so as to apply electric power for plasma generation.

When electric power for plasma generation is applied to the upper electrode 14, a radio-frequency electric field is applied between the upper electrode 14 and the stage 12 as the lower electrode. As a result, VHF waves from the periphery of the upper electrode 14 are introduced into the plasma generation space SP via the introduction part 16, and a sheath electric field is formed. When the sheath electric field as plasma power is applied to the introduced processing gas, plasma is generated and the temperature of the upper dielectric 181 facing the plasma rises. Since the conductive film 141 is electrically connected to the upper electrode 14 via the electromagnetic shielding material A, the conductive film 141 itself also has a function as the upper electrode 14. As the temperature of the upper dielectric 181 rises, the temperature of the conductive film 141 also rises. The heat radiation film 142 is provided on the conductive film 141. The higher the emissivity, the more heat can be efficiently radiated. Thus, heat is radiated by the heat radiation film 142, which makes it possible to apply more power to the upper electrode 14. Thus, the allowable upper limit of power for plasma generation becomes higher. In other words, when the supplied power for plasma generation is the same, it is possible to lower the temperature of the upper dielectric 181.

A conductive electromagnetic shielding material A is provided between the conductive film 141 and the upper electrode 14. When radio-frequency power such as VHF is used, radio-frequency electromagnetic waves may flow into the gas supply path from the gap between the conductive film 141 and the upper electrode 14. Such electromagnetic waves apply energy to the gas, which may cause unintended electrical discharge or the like. Since the conductive electromagnetic shielding material A is capable of filling the gap between the conductive film 141 and the upper electrode 14, it is possible to suppress unintended electrical discharge.

An annular sealing material B is provided between the upper dielectric 181 and the upper electrode 14. Since it is possible to form a space inside the annular sealing material B, it is possible to diffuse the gas, which is supplied in this space, in a radial direction and prevent the gas from leaking to the outside of the sealing material B. This makes it possible to prevent the leaking gas from receiving radio-frequency power such as VHF and generating electrical discharge.

The thermal conductivity of the sealing material B (O-ring) is preferably 0.4 (W/mK) or more. When the thermal conductivity of the sealing material is high, the heat dissipation characteristic of the dielectric is improved, and thus it is possible to lower the temperature of the dielectric. As an example of the sealing material B, the conductivity thereof is set as follows.

### Comparative Example 1: Thermal Conductivity is 0.19 (W/mK)

### Example 1: Thermal Conductivity is 1 (W/mK)

### Example 2: Thermal Conductivity is 2 (W/mK)

In the case of Comparative Example 1, when the temperature of the stage was set to 550 degrees C. and the temperature of the upper electrode 14 (the cooling part) was set to 150 degrees C., the maximum value of the temperature of the shower plate 18 was 342 degrees C., and the minimum value was 329 degrees C. (temperature change ΔT=13 degrees C.). When the temperature of the stage was set to 650 degrees C. and the temperature of the upper electrode 14 (the cooling part) was set to 45 degrees C., the maximum value of the temperature of the shower plate 18 was 307 degrees C., and the minimum value was 294 degrees C. (temperature change ΔT=13 degrees C.).

In the case of Example 1, when the temperature of the stage was set to 550 degrees C. and the temperature of the upper electrode 14 (the cooling part) was set to 150 degrees C., the maximum value of the temperature of the shower plate 18 was 326 degrees C., and the minimum value was 300 degrees C. (temperature change ΔT=26 degrees C.). When the temperature of the stage was set to 650 degrees C. and the temperature of the upper electrode 14 (the cooling part) was set to 45 degrees C., the maximum value of the temperature of the shower plate 18 was 283 degrees C., and the minimum value was 254 degrees C. (temperature change ΔT=29 degrees C.).

In the case of Example 2, when the temperature of the stage was set to 550 degrees C. and the temperature of the upper electrode 14 (the cooling part) was set to 150 degrees C., the maximum value of the temperature of the shower plate 18 was 311 degrees C., and the minimum value was 275 degrees C. (temperature change ΔT=36 degrees C.). When the temperature of the stage was set to 650 degrees C. and the temperature of the upper electrode 14 (the cooling part) was set to 45 degrees C., the maximum value of the temperature of the shower plate 18 was 261 degrees C., and the minimum value was 218 degrees C. (temperature change ΔT=43 degrees C.).

As described above, the thermal conductivity of the sealing material B (an O-ring) having a high thermal conductivity may be at least higher than the thermal conductivity of 0.19 (W/mK) of Comparative Example 1, and is preferably equal to or higher than a thermal conductivity between those of Comparative Example 1 and Example 1. That is, such a thermal conductivity is preferably 0.4 (W/mK), which is higher than that of Comparative Example 1 by about 25% of the difference between those of Comparative Example 1 and Example 1, or higher. In addition, the thermal conductivity is preferably 0.5 (W/mK), which is higher than that of Comparative Example 1 by about 40% of the difference between those of Comparative Example 1 and Example 1, or higher. The thermal conductivity may be set to 1 (W/mK) of Example 1 or higher. In this case, it is possible to maintain the temperature of the shower plate low.

An annular sealing material C having the same characteristics as those described above and a high thermal conductivity is also interposed between the upper dielectric 181 and the introduction part 16. The material of this sealing material is, for example, fluororubber such as “tetrafluoroethylene-perfluoromethyl vinyl ether rubber” (FFKM: perfluoroelastomer) and vinylidene fluoride-based rubber (FKM). The thermal conductivity of the sealing material C is 0.4 W/mK or higher. A high thermal conductivity filler, such as MN whiskers, may be contained in fluororubber so as to adjust the thermal conductivity to a desired value.

The processing container 10 has a substantially cylindrical shape. The processing container 10 extends in the vertical direction. The central axis of the processing container 10 is an axis AX extending in the vertical direction. The processing container 10 is formed of a conductor such as aluminum or an aluminum alloy. A corrosion-resistant film is formed on the surface of the processing container 10. The corrosion-resistant film is formed of ceramic such as aluminum oxide or yttrium oxide. The processing container 10 is grounded.

The stage 12 is provided within the processing container 10. The stage 12 is configured to support a substrate W placed on the top surface thereof substantially horizontally. The stage 12 has a substantially disk-like shape. The central axis of the stage 12 substantially coincides with the axis AX.

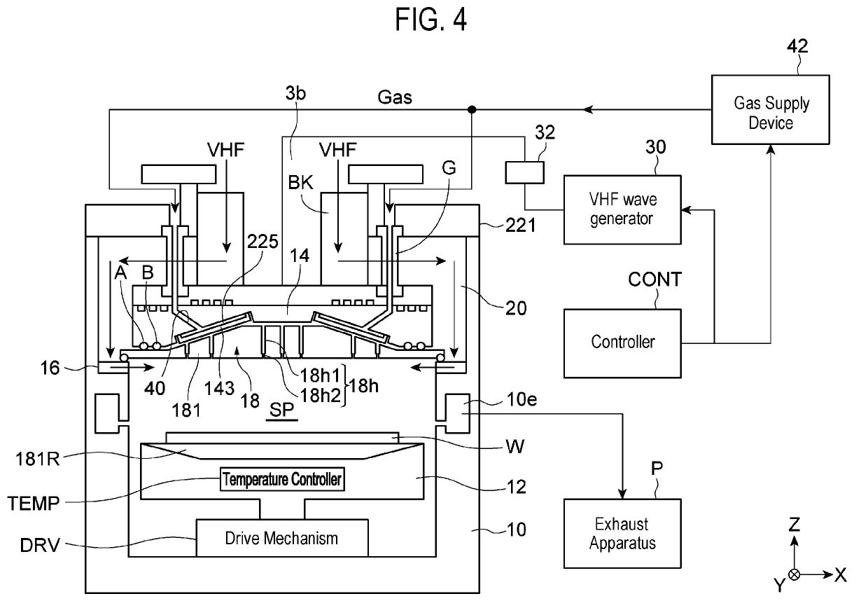

The plasma processing apparatus 1 may further include a baffle member 13. The baffle member 13 extends between the stage 12 and the side wall of the processing container 10. The baffle member 13 is a substantially annular plate material. The baffle member 13 is formed of an insulator such as aluminum oxide. Through holes are formed in the baffle member 13. The through holes penetrate the baffle member 13 in the plate thickness direction of the same. An annular exhaust port (an exhaust passage) 10e is formed on the lateral side of the processing container 10. An exhaust apparatus is connected to the exhaust port 10e. The exhaust apparatus P (see FIG. 4) includes a pressure control valve and a vacuum pump such as a turbo molecular pump and/or a dry pump.

The upper electrode 14 is installed above the stage 12, with a space SP within the processing container 10 being interposed therebetween. The upper electrode 14 is formed of a conductor such as aluminum or an aluminum alloy. The upper electrode 14 is a substantially disk-like shape. The central axis of the upper electrode 14 substantially coincides with the axis AX. The plasma processing apparatus 1 is configured to generate plasma in the space SP between the stage 12 and the upper electrode 14.

The plasma processing apparatus 1 further includes a shower plate 18. The shower plate 18 is installed directly below the upper electrode 14. The shower plate 18 faces the top surface of the stage 12 across the space SP. The space SP is the space between the shower plate 18 and the stage 12. The main body (the upper dielectric 181) of the shower plate 18 is made of an insulator such as aluminum nitride. The shower plate 18 has a substantially disk-like shape. The central axis of the shower plate 18 substantially coincides with the axis AX. Multiple gas ejection holes 18h (only one of which is illustrated in FIG. 1 because FIG. 1 is a simplified view) are formed in the shower plate 18 in order to evenly supply gas to the entire surface of the substrate W placed on the stage 12. The distance in the vertical direction between the bottom surface of the shower plate 18 and the top surface of the stage 12 is, for example, 5 cm or more and 10 cm or less.

In the plasma processing apparatus 1, the area of the inner wall surface of the processing container 10 extending above the baffle member 13 is substantially equal to the surface area of the shower plate 18 on the space SP side. That is, the area of a surface set to ground potential (a ground surface) among the surfaces defining the space SP is substantially equal to the area of the surface provided by the shower plate 18 among the surfaces defining the space SP. With this configuration, plasma is generated at a uniform density in the region directly below the shower plate and the region around the ground surface. As a result, the in-plane uniformity of plasma processing of the substrate W is improved.

An introduction part 16 is installed below the outside of the peripheral edge of the shower plate 18. That is, the introduction part 16 has a ring shape. The introduction part 16 is a part through which radio-frequency waves are introduced into the space SP. The radio-frequency waves are VHF waves. The introduction part 16 is installed at the lateral end portions of the space SP. The plasma processing apparatus 1 further includes a waveguide part 20 (a waveguide passage RF) in order to supply radio-frequency waves to the introduction part 16.

The waveguide part 20 provides a tubular waveguide 201 extending in the vertical direction. The central axis of the waveguide 201 substantially coincides with the axis AX. The lower end of the waveguide 201 is connected to the introduction part 16.

A radio-frequency power supply 30 is electrically connected to an outer surface 14w of the upper electrode 14 constituting the inner wall of the waveguide part 20 via a matcher 32. The radio-frequency power supply 30 is a power supply that generates the above-mentioned radio-frequency waves. The matcher 32 includes a matching circuit configured to match the impedance of the load of the radio-frequency power supply 30 with the output impedance of the radio-frequency power supply 30.

The waveguide 201 is provided by a space between the outer peripheral surface of the upper electrode 14 and the inner surface of a cylindrical member 24, which may be made of a conductor such as aluminum or an aluminum alloy.

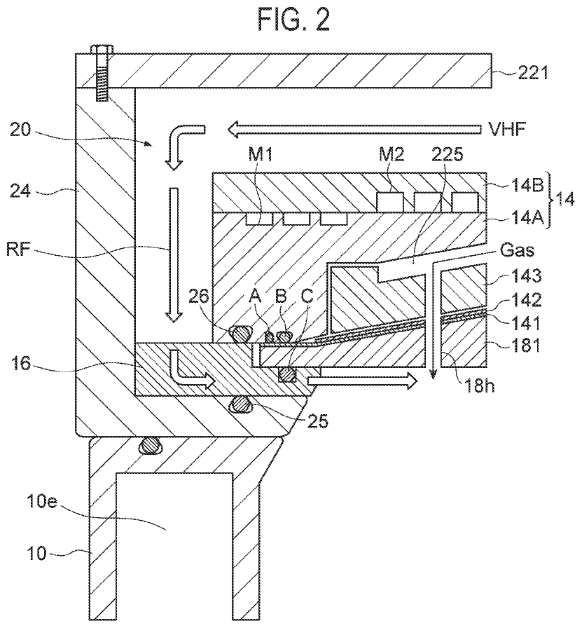

FIG. 2 is a view illustrating a certain structure of the structure illustrated in FIG. 1.

The introduction part 16 is elastically supported between the bottom surface of the outer peripheral region of the upper electrode 14 and the upper end surface of the main body of the processing container 10. A support member 25 is interposed between the bottom surface of the introduction part 16 and the upper end surface of the main body of the processing container 10. A support member 26 is interposed between the top surface of the introduction part 16 and the bottom surface of the outer peripheral region of the upper electrode 14. Each of the support member 25 and the support member 26 has elasticity. Each of the support member 25 and the support member 26 extends circumferentially around the axis AX of FIG. 1. Each of the support member 25 and the support member 26 is an O-ring made of, for example, silicone rubber.

The cylindrical member 24 is formed of a conductor such as aluminum or an aluminum alloy. The cylindrical member 24 has a substantially cylindrical shape. The central axis of the cylindrical member 24 substantially coincides with the axis AX of FIG. 1. The cylindrical member 24 extends in the vertical direction. The lower end of the cylindrical member 24 is connected to the upper end of the processing container 10, and the processing container 10 is grounded. Therefore, the cylindrical member 24 is grounded. At the upper end of the cylindrical member 24, an upper wall portion 221 forming the waveguide passage RF together with the top surface of the upper electrode 14 is located. In addition, the waveguides provided by the waveguide part 20 are constituted with grounded conductors.

A cooling part is installed in an upper portion of the upper electrode 14. The upper electrode 14 includes a first upper electrode 14A and a second upper electrode 14B located above the first upper electrode 14A. A concave groove M1 is formed in the top surface of the first upper electrode 14A, and a concave groove M2 is formed in the bottom surface of the second upper electrode 14B to be joined to the top surface of the first upper electrode 14A. The planar shape of these concave grooves is an annular shape or a spiral shape, and a cooling medium flows inside the concave grooves. Water or the like is used as the cooling medium, and the upper portion of the upper electrode also functions as a cooling jacket. The above-described electromagnetic shielding material A, sealing material B, and support member 26 are arranged in a recess formed in the bottom surface of the upper electrode, and the sealing material C is arranged in a recess formed in the top surface of the introduction part 16.

The shape of the upper dielectric 181 is thicker in the central portion and thinner in the peripheral portion, and the orientation and magnitude of an electric field vector of a sheath electric field may be corrected. Due to this shape, both the electric field vectors in the central portion and the peripheral portion are corrected so as to be parallel to each other in the direction perpendicular to the substrate.

Sheath electric fields that generate plasma tend to be strong in the central portion of the stage, and tend to be weak in the peripheral portion since electric field vectors are inclined. The conductive film 141 functions as an upper electrode during plasma generation. However, by forming electric fields via the upper dielectric 181 directly below the conductive film 141, it is possible to correct the inclination and strength of electric field vectors, and thus to improve the in-plane uniformity of sheath electric fields. This improves the in-plane uniformity of plasma. The conductive film 141 as the upper electrode is in contact with the sealing material B and the electromagnetic shielding material A. The heat radiation film 142 is not in contact with the sealing material B and the electromagnetic shielding material A located in the peripheral portion thereof. The processing gas introduced into the gas diffusion space 225 passes through the through holes 18h as gas ejection ports via the gas diffusion plate 143 having multiple holes, and is introduced into the plasma generation space.

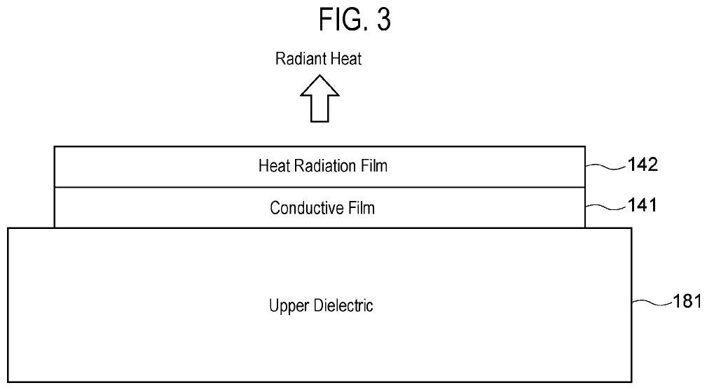

FIG. 3 is a view illustrating the structure of a laminated film according to an exemplary embodiment.

The conductive film 141 and the heat radiation film 142 are sequentially laminated on the upper dielectric 181. Each of the conductive film 141 and the heat radiation film 142 may include multiple layers. Examples of material combinations are as follows. An insulator is preferable as the material of the heat radiation film 142, but a semiconductor or conductor material having a high thermal emissivity may also be used. Since the heat radiation film is present, heat is radiated upward.

### Example 1

Heat radiation film 142: Al₂O₃

Conductive film 141: aluminum

### Example 2

Heat radiation film 142: TiO₂

Conductive film 141: aluminum

### Example 3

Heat radiation film 142: Y₂O₃

Conductive film 141: aluminum

### Example 4

Heat radiation film 142: YF

Conductive film 141: aluminum

It is also possible to turn the above-mentioned structure upside down and to use the structure on the lower electrode side. Thus, “top” in the above description may be replaced by “bottom”.

FIG. 4 is a view schematically illustrating a plasma processing apparatus according to an exemplary embodiment.

A gas diffusion space 225 is defined between the bottom surface of the upper electrode 14 and the shower plate 18 while the gas diffusion plate 143 is interposed therebetween. A pipe 40 is connected to the space 225. A gas supply device 42 is connected to the pipe 40. The gas supply device 42 includes one or more gas sources used for processing the substrate W. In addition, the gas supply device 42 includes one or more flow controllers configured to control the flow rates of gases from the one or more gas sources, respectively.

The pipe 40 extends to the space 225 through the waveguide of the waveguide part 20. As described above, all of the waveguides provided by the waveguide part 20 are constituted with grounded conductors. Therefore, the excitation of gas within the pipe 40 is suppressed. A gas supplied to the space 225 is ejected into the space SP via the multiple gas ejection holes 18h in the shower plate 18.

In the plasma processing apparatus 1, radio-frequency waves are supplied from the radio-frequency power supply 30 (a VHF generator) to the introduction part 16 through the waveguide of the waveguide part. The radio-frequency waves are VHF waves. The radio-frequency waves are introduced into the space SP from the introduction part 16 toward the axis AX. Radio-frequency waves are introduced into the space SP from the introduction part 16 with uniform power in the circumferential direction. When radio-frequency waves are introduced into the space SP, the gas is excited within the space SP, and plasma is generated from the gas. Accordingly, the plasma is generated in the space SP with a uniform density distribution in the circumferential direction. The substrate W on the stage 12 is processed with chemical species from the plasma.

The stage 12 is provided with a conductive layer for an electrostatic chuck and a conductive layer for a heater. The stage 12 has a main body, the conductive layer for the electrostatic chuck, and the conductive layer for the heater. The main body may be made of a conductor such as aluminum for functioning as a lower electrode. However, as an example, the main body is formed by embedding a lower dielectric 181R made of aluminum nitride or the like in the upper portion of the main body made of such a conductor. The main body has a substantially disk-like shape. The central axis of the main body substantially coincides with the axis AX. The conductive layer of the stage is made of a conductive material such as tungsten. The conductive layer is installed in the main body. The stage 12 may have one or more conductive layers. When a DC voltage from a DC power source is applied to the conductive layer for the electrostatic chuck, an electrostatic attraction is generated between the stage 12 and the substrate W. The substrate W is attracted to the stage 12 by the generated electrostatic attraction, and is held by the stage 12. In another embodiment, the conductive layer may be a radio-frequency electrode. In this case, a radio-frequency power supply is electrically connected to the conductive layer via a matcher. In yet another embodiment, the conductive layer may be an electrode that is grounded. The conductive layer embedded in such an insulator may also function as a lower electrode for forming an electric field between the upper electrode and the lower electrode.

In the embodiment, the shower plate 18 made of a dielectric is disposed below an upper portion wall constituting a bulk upper electrode 14 of the processing container 10, with a gas diffusion space 225 interposed therebetween. The bottom surface of the upper portion wall has a recess, and a gas from the gas supply device 42 flows through the inside of the recess. The pipe 40 is connected to the gas diffusion space 225 in the recess. The gas ejection holes 18h in the shower plate 18 are located below the gas diffusion space 225. The shape of one or more recesses may be circular or ring-shaped, but all the recesses communicate with each other such that the gas diffuses in a substantially horizontal direction. The gas ejection hole 18h includes a first through hole 18h1 located in the upper portion thereof and a second through hole 18h2 located in the lower portion thereof. The inner diameter of the first through hole 18h1 is larger than the inner diameter of the second through hole 18h2, and the first through hole 18h1 and the second through holes 18h2 communicate with each other. According to Bernoulli's theorem, the flow velocity of gas is higher in a thinner one than in a thicker one. The gas diffused in the gas diffusion space 225 is introduced into the second through holes 18h2 having a thin inner diameter, and the flow velocity at the time of ejection is limited by this diameter. This structure is capable of adjusting the flow velocity of the gas.

The main body (the upper dielectric 181) of the shower plate 18 is made of a dielectric made of ceramic. A conductive film 141, which functions as an upper electrode, is provided on the upper surface of the upper dielectric 181. One or more electromagnetic shielding materials A, which are annular conductive sealing materials (spiral shields), are provided on the upper surface of the peripheral portion of the conductive film 141. The conductive film 141 as the upper electrode is in contact with the bottom surface of the bulk upper electrode 14, with the electromagnetic shielding material A interposed therebetween, and is electrically connected to the bottom surface of the bulk upper electrode 14. Since the bulk upper electrode 14 is connected to the radio-frequency power supply 30 (the VHF wave generator) via the matcher 32, a radio-frequency voltage is applied between the conductive film 141 and the ground potential. The material of the upper dielectric 181 is ceramic, and the material constituting the upper dielectric 181 is aluminum nitride (AlN), alumina (Al₂O₃), or the like. The material constituting the conductive film 141 is aluminum or the like. The conductive film material may be deposited on the top surface of the upper dielectric 181 through sputtering, chemical vapor deposition (CVD), or thermal spraying.

The stage 12 has a built-in temperature controller TEMP such as a heater, and the position of the stage may be shifted by a drive mechanism DRV, which moves up, down, left, and right. In addition, VHF waves are introduced from the upper opening of the processing container, and an insulator block BK for radio-frequency matching can be arranged immediately below the opening. The insulator block BK is made of SiO₂ or Al₂O₃. When a processing gas passage crosses a VHF wave passage path up and down, a gas passage G, which connects a gas passage in the upper wall portion 221 and a gas passage in the upper electrode 14, may be provided. The gas passage G includes of two concentric insulating cylinders, and is made of, for example, SiO₂ or Al₂O₃. The above-mentioned elements are controlled by a controller CONT.

### EXPLANATION OF REFERENCE NUMERALS

1: plasma processing apparatus, 10: processing container, 10e: exhaust port, 12: stage (lower electrode), 14: upper electrode, 141: conductive film (upper electrode), 16: introduction part, 18: shower plate, 18h: gas ejection hole, 24: cylindrical member, 25: support member, 26: support member, 30: radio-frequency power supply, 32: matcher, 40: pipe, 42: gas supply device, 225: space, RF: waveguide passage, SP: space, W: substrate, 142: heat radiation film, 143: gas diffusion plate.

1. A plasma processing apparatus comprising:
a dielectric including one surface which faces a space for plasma generation;
a conductive film installed on the other surface of the dielectric;
a heat radiation film installed on the conductive film, and having a higher emissivity than the conductive film; and
an electrode electrically connected to the conductive film so as to apply electric power for plasma generation.

2. The plasma processing apparatus of claim 1, wherein a conductive electromagnetic shielding material is installed between the conductive film and the electrode.

3. The plasma processing apparatus of claim 2, wherein an annular sealing material is installed between the dielectric and the electrode.

4. The plasma processing apparatus of claim 1, wherein an annular sealing material is installed between the dielectric and the electrode.
